(19) United States
(12) Patent Application Publication
(10) Pub. No.: US 2022/0328513 A1
(43) Pub. Date: Oct. 13, 2022

(54) MEMORY DEVICE AND METHOD OF FABRICATING THE SAME

(71) Applicant: Winbond Electronics Corp., Taichung City (TW)

(72) Inventors: Frederick Chen, San Jose, CA (US); Riichiro Shirota, Kanagawa (JP)

(73) Assignee: Winbond Electronics Corp., Taichung City (TW)

(21) Appl. No.: 17/227,383

(22) Filed: Apr. 12, 2021

(51) Int. Cl. H01L 27/11582; H01L 27/11556; H01L 27/1157; H01L 27/11524

(52) U.S. Cl. CPC H01L 27/11582; H01L 27/11556; H01L 27/1157; H01L 27/11524

(57) ABSTRACT

A memory device and method of fabricating the same are provided. The memory device includes a substrate, a stacked structure, a channel layer, and a charge storage structure. The stacked structure is located on the substrate and includes a plurality of insulating layers and a plurality of conductive layers stacked alternately, and the stacked structure has holes. The channel layer is located in the hole and includes a first part and a second part. The number of grain boundaries in the second part is less than the number of grain boundaries in the first part. The charge storage structure is located between the first part and the plurality of conductive layers, and the charge storage structure and the second part sandwich the first part therebetween.

### BACKGROUND

### Technical Field

The embodiment of the present invention relates to a semiconductor device and method of fabricating the same, and particularly relates to a memory device and method of fabricating the same.

### Description of Related Art

Since flash memory has the advantage that the stored data does not disappear after power off, it becomes a widely used memory device for many electronic devices. Although three dimensional NAND flash memory developed with the evolution of processes may improve the integration density of memory devices, there still exist many related challenges.

### SUMMARY

The present invention provides a memory device and a method of fabricating the same, which may improve the quality of the channel layer and reduce the variation of the read current.

An embodiment of the present invention provides a memory device. The memory device includes a substrate, a stacked structure, a channel layer and a charge storage structure. The stacked structure is disposed on the substrate and includes a plurality of insulating layers and a plurality of conductive layers stacked alternatively. The stacked structure has a hole therein. The channel layer is disposed in the hole and includes a first part and a second part. A number of grain boundaries of the second part is less than a number of grain boundaries of the first part. The charge storage structure is disposed between the first part and the plurality of conductive layers, and the first part is sandwiched between the charge storage structure and the second part.

An embodiment of the present invention provides a fabricating method of a memory device, including: forming a stacked structure on a substrate, the stacked structure includes a plurality of insulating layers and a plurality of conductive layers stacked alternately; forming a hole in the stacked structure; forming a charge storage structure on a sidewall of the stacked structure in the hole; forming a channel layer in the hole which include forming a first part on a sidewall of the charge storage structure in the hole and forming a second part on a sidewall of the first part in the hole, wherein the number of grain boundaries of the second part is less than the number of grain boundaries of the first part.

Another embodiment of the present invention provides a fabricating method of a memory device, including: forming a stacked structure on a substrate, the stacked structure includes a plurality of first material layers and a plurality of second material layers stacked alternately; forming a hole in the stacked structure; forming a channel layer in the hole which includes forming a first part on a sidewall of the stacked structure in the hole and forming a second part on a sidewall of the first part in the hole, and the number of grain boundaries of the second part is less than the number of grain boundaries of the first part; forming a filling layer in the hole to cover a sidewall of the second part; replacing the plurality of second material layers with a plurality of conductive layers; and forming a charge storage structure between the plurality of conductive layers and the plurality of first material layers.

In view of above, in many embodiments of the present invention, the channel layer includes a first part and a second part. The second part has low density of grain boundaries, which may reduce the variation of read current.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1D are schematic cross-sectional views illustrating intermediate stages in a fabricating method of a semiconductor device according to an embodiment of the present invention.

FIG. 2A to FIG. 2I are schematic cross-sectional views illustrating intermediate stages in a fabricating method of a three dimensional memory device according to an embodiment of the present invention.

FIG. 3A to FIG. 3D are schematic cross-sectional views illustrating intermediate stages in a fabricating method of a three dimensional memory device according to another embodiment of the present invention.

### DESCRIPTION OF THE EMBODIMENTS

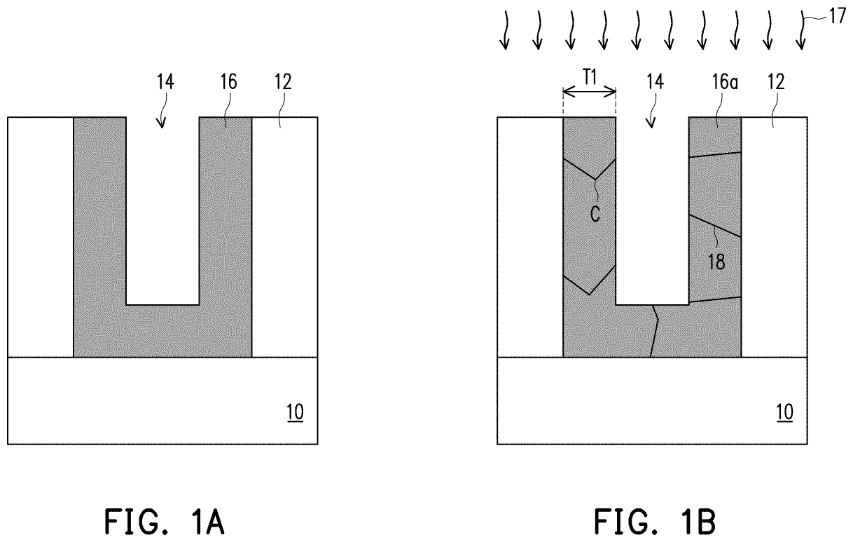

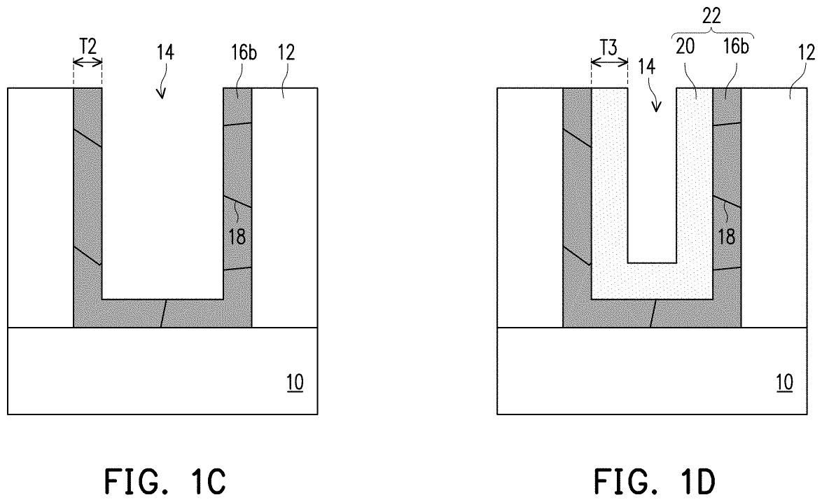

FIG. 1A to FIG. 1D are schematic cross-sectional views illustrating intermediate stages in a fabricating method of a semiconductor device according to an embodiment of the present invention.

Referring to FIG. 1A, a substrate 10 is provided. The substrate 10 may be a semiconductor substrate, such as a silicon-containing substrate. A dielectric layer 12 having an opening 14 is formed on the substrate 10. The dielectric layer 12 may be a single layer, a composite layer, or a stacked layer. The substrate 10 and the dielectric layer 12 may include some other layers or components. An amorphous silicon layer 16 is formed on the sidewall of the dielectric layer 12 in the opening 14. The amorphous silicon layer 16 may be formed by depositing an amorphous silicon material layer by a chemical vapor deposition method. The amorphous silicon layer 16 may have dopant or free of dopant. The dopant may be P-type dopant, such as boron, or N-type dopant, such as phosphorus or arsenic. The amorphous silicon layer 16 has a plurality of grain boundaries 18 therein.

Referring to FIG. 1B, an annealing process 17 is performed on the amorphous silicon layer 16 so as to form a polycrystalline silicon layer 16a. The polycrystalline silicon layer 16a has a plurality of grain boundaries 18 therein. A plurality of intersection points C is existed between the grain boundaries 18. The thickness T1 of the polycrystalline silicon layer 16a ranges from, for example, 10 nm to 20 nm.

Referring to FIG. 1B and FIG. 1C, if the thickness T1 of the polycrystalline silicon layer 16a is relatively thick, and the number of the grain boundaries 18 and the intersection point C are relatively large, it would adversely affect the flow of the current. The embodiment of the present invention may selectively reduce the thickness T1 of the polycrystalline silicon layer 16a by performing an etching process such as an anisotropic etching process to form an polycrystalline silicon layer 16b having a thickness T2. The thickness T2 of the polycrystalline silicon layer 16b ranges from, for example, 1 nm to 5 nm. The density of the grain boundaries 18 in the polycrystalline silicon layer 16b is reduced due to the thickness reduction. The intersection points C between grain boundaries 18 is thus reduced or eliminated.

Referring to FIG. 1D, an epitaxial process is performed to form epitaxial silicon layer 20 on sidewalls of the polycrystalline silicon layer 16b in the opening 14. The epitaxial silicon layer 20 may not fill up the opening 14 or may fill up the remaining space of the opening 14 (not shown). The method of forming the epitaxial silicon layer 20 includes, for example, a hot-wire chemical vapor deposition method. In some embodiments, the deposition is performed using SiH₄ in Ar, and performed at a temperature of 400-550 degrees Celsius and under a pressure of 1E⁻² to 1 Torr. The epitaxial silicon layer 20 and the polycrystalline silicon layer 16b may be collectively used as a channel layer 22. The polycrystalline silicon layer 16b is used as a first part P1 of the channel layer 22; the epitaxial silicon layer 20 is used as a second part P2 of the channel layer 22. In some embodiments, a thickness T3 of the second part P2 of the channel layer 22 accounts for 75% to 95% of the overall thickness (T2+T3) of the channel layer 22. Compared with the polycrystalline silicon layer 16b, the density of grain boundaries of the epitaxial silicon layer 20 is lower. Therefore, the density of grain boundaries of the second part P2 of the channel layer 22 is less than the density of grain boundaries of the first part P1. When the channel layer 22 is applied to a memory device, the variation of the read current may be reduced. Although the channel layer 22 uses the polycrystalline silicon layer 16b as the first part P1 and the epitaxial silicon layer 20 as the second part P2 for exemplary illustration, the disclosure is not limited thereto. In some other embodiments, other suitable types of polycrystalline layer and epitaxial layer may also be used as the first part P1 and the second part P2 of the channel layer 22, respectively.

The above process of forming the channel layer may be applied to the process for memory device, which is exemplarily illustrated as below.

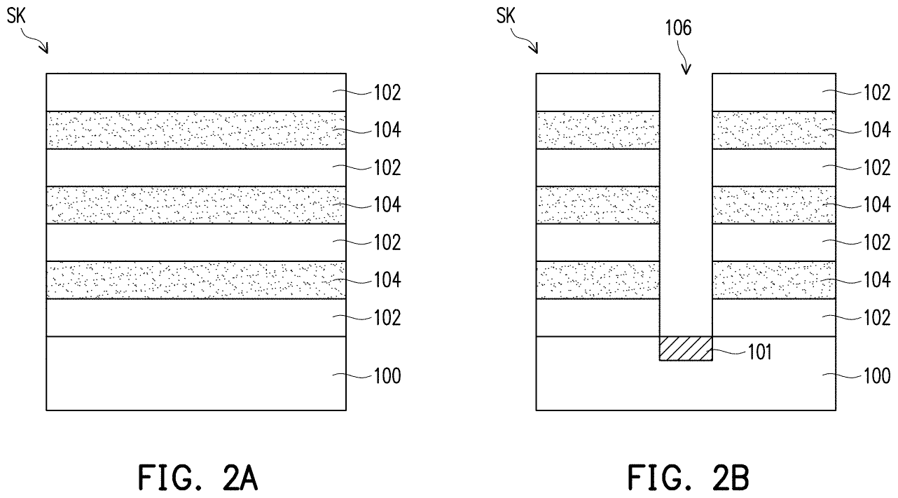

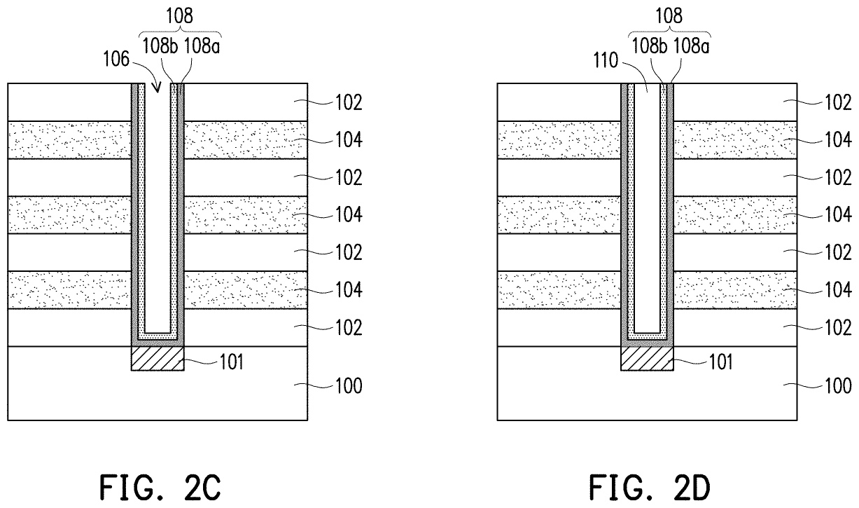

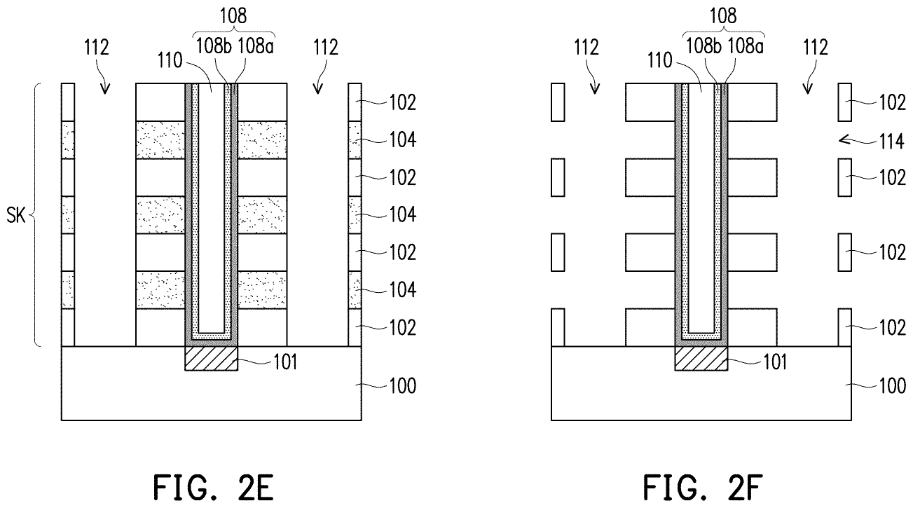

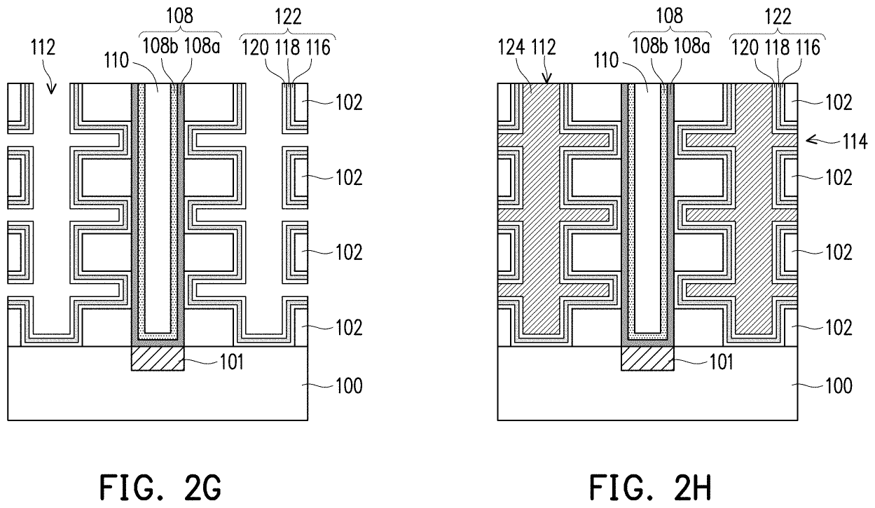

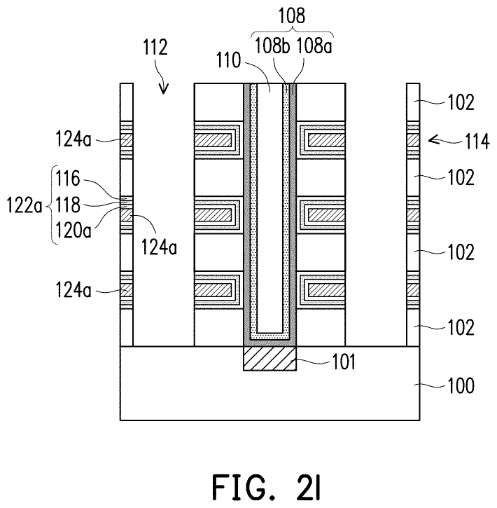

FIG. 2A to FIG. 2I are schematic cross-sectional views illustrating intermediate stages in a fabricating method of a three dimensional memory device according to an embodiment of the present invention.

Referring to FIG. 2A, a substrate 100 is provided. The substrate 100 may be a semiconductor substrate, such as a silicon-containing substrate. In an embodiment, the substrate 100 may further include a device layer (not shown) on the semiconductor substrate and a metal interconnection structure (not shown) may be formed on the device layer. The device layer may include active devices or passive devices. Active devices are, for example, transistors, diodes, or the like. Passive devices are, for example, capacitors, inductors, or the like. The metal interconnection structure may include dielectric layers (not shown), plugs 101 and wires (not shown), or the like. The plug 101 may be electrically connected to a source line. The material of the plug 101 may include tungsten.

Referring to FIG. 2A, a stacked structure SK is formed over the substrate 100. The substrate 100 may be a semiconductor substrate, such as a silicon substrate. The stacked structure SK includes a plurality of first material layers 102 and a plurality of second material layers 104 stacked alternately. The first material layer 102 may be insulating layer, such as silicon oxide. The second material layer 104 may be insulating layer, such as silicon nitride. In the embodiment, both the bottommost layer and the topmost layer of the stacked structure SK are the first material layer 102, but the invention is not limited thereto. In addition, in the present embodiment, four layers of first material layers 102 and three layers of second material layers 104 are used for illustration, but the present invention is not limited thereto.

Next, referring to FIG. 2B, a patterning process is performed to remove portions of the stacked structure SK in a memory array region, so as to form one or more holes 106 penetrating through the stacked structure SK. In an embodiment, the hole 106 may have a substantially vertical sidewall. In another embodiment, the hole 106 may have a slightly inclined sidewall (not shown).

Referring to FIG. 2C, a channel layer 108 is formed on the sidewall of the hole 106. The channel layer 108 may be formed by the method for forming the channel layer 22 in the above-described embodiment. That is, the channel layer 108 may include a first part 108a and a second part 108b. The first part 108a is connected to the plug 101, and the second part 108b covers the first part 108a. The first part 108a is, for example, a polycrystalline silicon layer; the second part 108b is, for example, an epitaxial silicon layer. The polycrystalline silicon layer and the epitaxial silicon layer may be formed by the methods of forming the polycrystalline silicon layer 16b and the epitaxial silicon layer 20 described in the above embodiments, respectively. The channel layer 108 is, for example, a conformal layer without filling up the hole 106.

Referring to FIG. 2D, a filling layer 110 is filled in the hole 106. The material of the filling layer 110 is silicon oxide, for example.

FIG. 2E to FIG. 2I illustrate replacing the second material layer 104 with conductive layers 124a, and forming a charge storage structure 122a between the conductive layer 124a and the first material layer 102, which will be described in detail below.

Referring to FIG. 2E, lithography and etching processes are performed to form slits 112 in the stacked structure SK. The trench 112 exposes a plurality of first material layers 102 and a plurality of second material layers 104 of the stacked structure SK.

Referring to FIG. 2F, an etchant is injected/introduced through the trench 112 to remove the plurality of second material layers 104 of the stacked structure SK, so as to form a plurality of horizontal openings 114. The horizontal openings 114 expose the plurality of first material layers 102 of the stacked structure SK and the channel layer 108.

Referring to FIG. 2F and FIG. 2G, a charge storage structure 122 is formed in the slits 112 and the horizontal openings 114. The charge storage structure 122 includes, for example, a silicon oxide layer 116, a silicon nitride layer 118, and a high-k dielectric layer 120. The high-k dielectric layer 120 is a dielectric layer with a dielectric constant greater than 4, such as Al₂O₃, HfO₂, ZrO₂, Ta₂O₅, TiO₂, or a combination thereof. The silicon oxide layer 116, the silicon nitride layer 118, and the high-k dielectric layer 120 are, for example, conformal layers, which may be formed by chemical vapor deposition methods or atomic layer deposition methods.

Referring to FIG. 2H, a conductive layer 124 is formed in the slits 112 and the horizontal openings 114 to cover the charge storage structure 122. The conductive layer 124 is, for example, tungsten, titanium, or tantalum, and may be formed by, for example, a chemical vapor deposition method.

Referring to FIG. 2I, the conductive layer 124 and the high-k dielectric layer 120 of the charge storage structure 122 in the trench 112 are removed, remaining a conductive layer 124a and a charge storage structure 122a in the horizontal opening 114. The charge storage structure 122a includes the silicon oxide layer 116, the silicon nitride layer 118, and the high-k dielectric layer 120a.

Thereafter, subsequent processes may be performed to complete the fabrication of the three dimensional memory device.

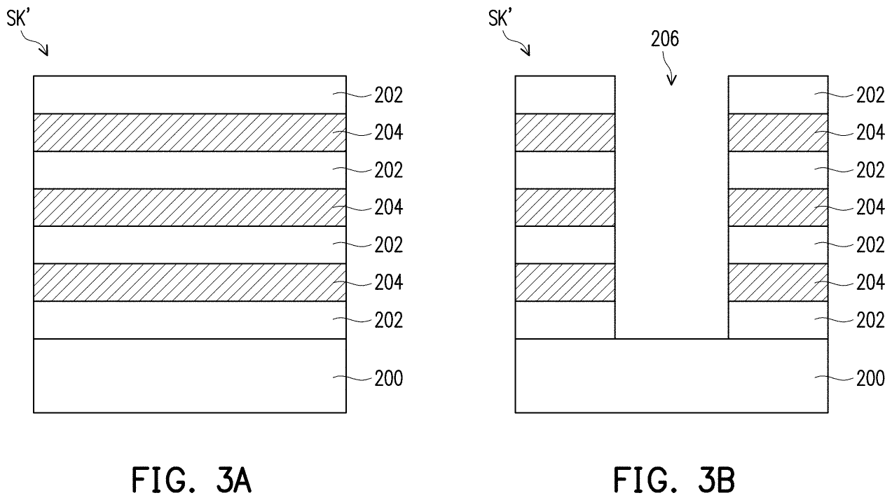

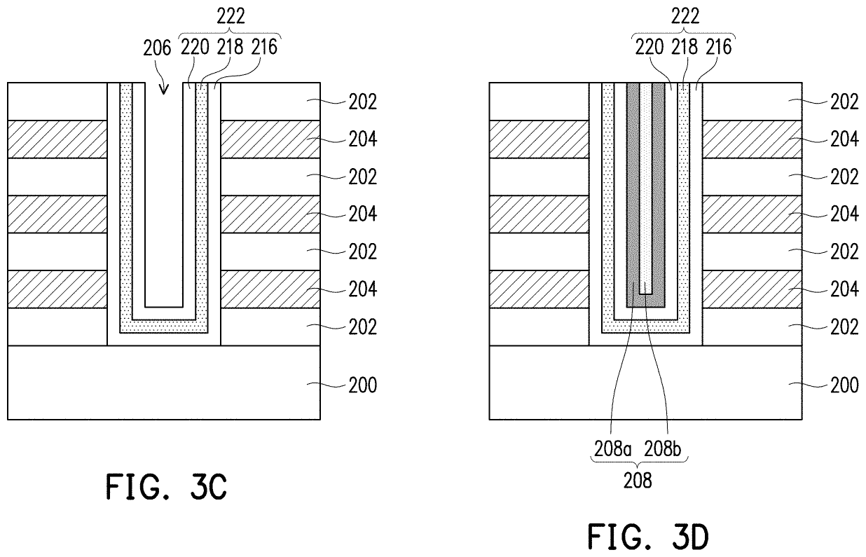

FIG. 3A to FIG. 3D are schematic cross-sectional views illustrating intermediate stages in a fabricating method of a three dimensional memory device according to another embodiment of the present invention.

Referring to FIG. 3A, a substrate 200 is provided. The substrate 200 may be a semiconductor substrate, such as a silicon-containing substrate. In one embodiment, a doped region may be formed in the substrate 200 according to design requirements. A device layer (not shown) and a metal interconnection structure (not shown) may be formed on the substrate 200. The device layer may include active devices or passive devices. Active devices are, for example, transistors, diodes, or the like. Passive devices are, for example, capacitors, inductors, or the like. The metal interconnection structure may include dielectric layers, plugs and wires, or the like.

Referring to FIG. 3A, a stacked structure SK′ is formed over the substrate 200. The stacked structure SK′ includes a plurality of first material layers 202 and a plurality of second material layers 204 stacked alternately. The first material layer 202 may be insulating layer, such as silicon oxide. The second material layer 204 may be polycrystalline silicon layer. In the present embodiment, both the bottommost layer and the topmost layer of the stacked structure SK′ are the first material layer 202, but the invention is not limited thereto. In addition, in the present embodiment, four layers of first material layers 202 and three layers of second material layers 204 are used for illustration, but the present invention is not limited thereto.

Next, referring to FIG. 3B, a patterning process is performed to remove a portion of the stacked structure SK′ to form one or more holes 206 penetrating through the stacked structure SK′. In an embodiment, the hole 206 may have a substantially vertical sidewall. In another embodiment, the hole 206 may have a slightly inclined sidewall (not shown).

Referring to FIG. 3C, a charge storage structure 222 is formed on the sidewall of the hole 206. The charge storage structure 222 includes, for example, a silicon oxide layer 216, a silicon nitride layer 218, and a silicon oxide layer 120. The silicon oxide layers 116 and 120 and the silicon nitride layer 118 are, for example, conformal layers, which may be formed by a thermal oxidation method or a chemical vapor deposition method.

Referring to FIG. 3D, a channel layer 208 is formed on the sidewall of the charge storage structure 222 in the hole 206. The channel layer 208 may be formed by the method for forming the channel layer 22 in the above-described embodiment. That is, the channel layer 208 may include a first part (for example, a polycrystalline silicon layer) 208a and a second part (for example, an epitaxial silicon layer) 208b. The second part 208b fills up the hole 206, but the present invention is not limited thereto. The polycrystalline silicon layer and the epitaxial silicon layer may be formed by the methods of forming the polycrystalline silicon layer 16b and the epitaxial silicon layer 20 described in the above-mentioned embodiment, respectively, which are not described again here.

Thereafter, subsequent processes may be performed to complete the fabrication of the three dimensional memory device.

In many embodiments of the present invention, the channel layer includes an amorphous silicon layer and an epitaxial silicon layer. The low density of grain boundaries of epitaxial silicon layer may reduce the variation of read current. In addition, the thickness of the amorphous silicon layer may be reduced to reduce the number of grain boundaries and grain boundary intersection points, which may further reduce the variation of the read current.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a substrate;
a stacked structure, disposed on the substrate, comprising a plurality of insulating layers and a plurality of conductive layers stacked alternatively, the stacked structure has a hole;
a channel layer, disposed in the hole and comprising:
a first part; and
a second part, wherein a number of grain boundaries of the second part is less than a number of grain boundaries of the first part; and
a charge storage structure, disposed between the first part and the plurality of conductive layers, and the first part is sandwiched between the charge storage structure and the second part.

2. The memory device of claim 1, wherein the first part comprises polycrystalline silicon, and the second part comprises epitaxial silicon.

3. The memory device of claim 2, wherein a thickness of the second part is 75% to 95% of an overall thickness of the channel layer.

4. The memory device of claim 1, wherein the charge storage structure is further disposed between the plurality of insulating layers and the plurality of conductive layers of the stacked structure.

5. The memory device of claim 4, further comprising a filling layer filled in the hole and covering a sidewall of the second part.

6. The memory device of claim 1, wherein the second part fills up the hole.

7. A method of fabricating a memory device, comprising:
forming a stacked structure on a substrate, the stacked structure comprises a plurality of insulating layers and a plurality of conductive layers stacked alternatively;
forming a hole in the stacked structure;
forming a charge storage structure on a sidewall of the stacked structure in the hole; and
forming a channel layer in the hole, comprising:
forming a first part on a sidewall of the charge storage structure in the hole; and
forming a second part on a sidewall of the first part in the hole, a number of grain boundaries of the second part is less than a number of grain boundaries of the first part.

8. The method of fabricating the memory device of claim 7, further comprising removing a portion of the first part to thin a thickness of the first part.

9. The method of fabricating the memory device of claim 7, wherein the first part comprises polycrystalline silicon, and the second part comprises epitaxial silicon.

10. The method of fabricating the memory device of claim 9, wherein a thickness of the second part is 75% to 95% of an overall thickness of the channel layer.

11. A method of fabricating a memory device, comprising:
forming a stacked structure on a substrate, the stacked structure comprise a plurality of first material layers and a plurality of second material layers;
forming a hole in the stacked structure;
forming a channel layer in the hole, comprising:
forming a first part on a sidewall of the stacked structure in the hole; and
forming a second part on a sidewall of the first part, a number of grain boundaries of the second part is less than a number of grain boundaries of the first part;
forming a filling layer in the hole to cover a sidewall of the second part;
replacing the plurality of second material layers with a plurality of conductive layers; and
forming a charge storage structure between the plurality of conductive layers and the plurality of first material layers.

12. The method of fabricating the memory device of claim 11, further comprising removing a portion of the first part to thin a thickness of the first part.

13. The method of fabricating the memory device of claim 11, wherein the first part comprises polycrystalline silicon, and the second part comprise epitaxial silicon.

14. The method of fabricating the memory device of claim 13, wherein a thickness of the second part is 75% to 95% of an overall thickness of the channel layer.
